(19) United States
(12) Patent Application Publication
(10) Pub. No.: US 2025/0331353 A1
(43) Pub. Date: Oct. 23, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Chi Yu, Beijing (CN); Zhenhua Zhang, Beijing (CN); Tong Wu, Beijing (CN); Ming Hu, Beijing (CN); Zhiliang Jiang, Beijing (CN); Ge Wang, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/859,303

(22) PCT Filed: Jan. 2, 2024
(86) PCT No.: PCT/CN2024/070019

§ 371 Date: Oct. 23, 2024

(30) Foreign Application Priority Data
Jan. 20, 2023 (CN) 202310084007.5

(51) Int. Cl. H10H 29/80

(52) U.S. Cl. CPC H10H 29/8321; H10H 29/8322

(57) ABSTRACT

A display panel and a display device are provided by the embodiments of the present disclosure. The display panel includes a first displaying region and a second displaying region. The second displaying region is located within the first region of the displaying surface of the display panel. There are a plurality of cathodes that are arranged in a predetermined pattern, and a plurality of cathode-removal regions in the second displaying region, wherein at least two cathodes in the plurality of cathodes are connected in parallel. The first region refers to a region that faces the region of the bottom of the displaying surface of the display panel where an optical functional element is disposed. In this way, the resistance of the cathodes can be reduced, to prevent obvious local voltage drop in the second displaying region.

### CROSS REFERENCE TO RELEVANT APPLICATIONS

The present application claims the priority of the Chinese patent application filed on Jan. 20, 2023 before the Chinese Patent Office with the application number of 202310084007.5 entitled “DISPLAY PANEL AND DISPLAY APPARATUS”, which is incorporated herein in its entirety by reference.

### TECHNICAL FIELD

The present disclosure relates to the technical field of display devices and, more particularly, to a display panel and a display device.

### BACKGROUND

With the continuous development of display devices, the display panels of the display devices are increasingly evolving towards the trends of a lighter and thinner screen, a wider visual angle, flexible displaying and a lower power consumption. The display devices with a full screen are becoming increasingly popular among users. During the development process of full screens, methods such as the notch screen, the popping-up screen, the water-drop screen and the hole-punch screen have been used to increase the screen-to-body ratio of the display devices. However, all of these methods compromise the effect of displaying of the display panel to a certain extent, and they are not a full screen in the true sense. That the functional elements such as the camera and the photosensor are completely hidden under the display panel, to increase the screen-to-body ratio of the display devices to the largest extent, has become a mainstream method currently.

Currently, in order to satisfy the normal light sensation of the functional devices, to increase the transmittance of the region where the functional elements are located, usually the cathode is patterned.

However, after the cathode are patterned, i.e., removing the cathode to form cathode-removal regions, the resistance of the cathode increases, which results in obvious voltage drop of partial region of the display panel, to cause the region where the functional elements are located in the display panel to be dark and the effect of displaying of the display panel to be affected.

### SUMMARY

A display panel and a display device are provided by the embodiments of the present disclosure to solve the problem in the related art of local darkness caused by obvious local voltage drop of the display panel.

In order to solve the above technical problem, the present disclosure is realized as follows:

In a first aspect, a display panel is provided by an embodiment of the present disclosure, wherein the display panel includes a first displaying region and a second displaying region;
the second displaying region is located within a first region of a displaying surface of the display panel; and
there are a plurality of cathodes that are arranged in a predetermined pattern and a plurality of cathode-removal regions in the second displaying region, wherein at least two cathodes in the plurality of cathodes are connected in parallel; and
the first region refers to a region that faces a region of a bottom of the displaying surface of the display panel where an optical functional element is disposed.

Optionally, the plurality of cathodes contained in the second displaying region are arranged in a net-like pattern.

Optionally, there are first cathodes and second cathodes in the second displaying region;
the first cathodes extend along a pixel row direction, and multiple first cathodes are arranged equidistantly along a pixel column direction; and
the second cathodes and the first cathodes intersect, so that the multiple first cathodes are connected in parallel.

Optionally, an included angle between each of the first cathodes and each of the second cathodes is an acute angle.

Optionally, an included angle between each of the first cathodes and each of the second cathodes is a right angle.

Optionally, the display panel further includes a substrate; and
the cathodes are disposed on the substrate, and a light-exiting adjusting component is disposed at one side of the cathodes away from the substrate.

Optionally, a material of the cathodes includes a metal or an alloy, and a material of the light-exiting adjusting component is a metal oxide; and a transmittance of the light-exiting adjusting component is greater than a transmittance of the cathodes.

Optionally, the display panel includes a plurality of pixel units;
each of the pixel units includes a plurality of sub-pixel units of different colors;
distances between each of the cathodes and each of the sub-pixel units of neighboring pixel units are equal; and the cathodes are arranged in an array.

Optionally, each of the pixel units includes a red sub-pixel unit, a green sub-pixel unit and a blue sub-pixel unit;
the red sub-pixel units and the green sub-pixel units are arranged alternately and separately along a pixel row direction, and the red sub-pixel units and the green sub-pixel units are arranged alternately and separately along a pixel column direction; and
the blue sub-pixel units are located between two rows of the green sub-pixel units and the red sub-pixel units that are arranged alternately and separately.

Optionally, the cathodes are located between neighboring red sub-pixel units and green sub-pixel units in the pixel column direction, or located between neighboring red sub-pixel units and green sub-pixel units in the pixel row direction.

Optionally, the blue sub-pixel units are located in gaps between two neighboring rows of the green sub-pixel units and the red sub-pixel units that are arranged alternately and separately.

Optionally, each of the pixel units includes a red sub-pixel unit, a green sub-pixel unit and a blue sub-pixel unit; and
the red sub-pixel unit, the green sub-pixel unit and the blue sub-pixel unit that are included by each of the pixel units surround one cathode, and the cathode deviates from the blue sub-pixel unit.

Optionally, the second displaying region includes a middle region and a peripheral region surrounding the middle region; and
a quantity of the cathode-removal regions disposed in the middle region is greater than a quantity of the cathode-removal regions disposed in the peripheral region.

Optionally, the quantity of the cathode-removal regions sequentially increases from the peripheral region to the middle region.

Optionally, in the second displaying region, a ratio of an area occupied by the cathode-removal regions to an area occupied by the cathodes is between 0.1 and 1.

Optionally, a pixel density of the second displaying region is a preset multiple of a pixel density of the first displaying region, so that a transmittance of the second displaying region is greater than a transmittance of the first displaying region.

Optionally, the display panel further includes a third displaying region; and
the third displaying region is located between the first displaying region and the second displaying region, and a pixel density of the third displaying region is greater than the pixel density of the second displaying region, and less than the pixel density of the first displaying region.

Optionally, a resistance of the cathodes within the third displaying region is greater than a resistance of the cathodes within the second displaying region, and less than a resistance of the cathodes within the first displaying region.

Optionally, a shape of the second displaying region is any one of a circle, a square, an ellipse, a rhombus, a polygon and an irregular pattern.

In a second aspect, a display device is further provided by the embodiments of the present application, wherein the display device includes functional elements and the display panel according to any one of embodiments in the first aspect; and projections, on a substrate base board, of sensing components or function triggering components of the functional elements at least partially overlap with projections of the cathode-removal regions on the substrate base board.

It can be seen from the above embodiments that, in the embodiments of the present disclosure, because the second displaying region is located within the first region of the displaying surface of the display panel, the first region refers to a region that faces the region of the bottom of the displaying surface of the display panel where an optical functional element is disposed, and there are a plurality of cathodes that are arranged in a predetermined pattern and a plurality of cathode-removal regions in the second displaying region, under the effect of the cathode-removal regions, the pixel density of the second displaying region is less than the pixel density of the first displaying region; in other words, the transmittance of the second displaying region is less than the transmittance of the first displaying region, to satisfy the demand on light sensation of the functional elements. In addition, because at least two cathodes in the plurality of cathodes are connected in parallel, the resistance of the cathodes can be reduced, to prevent obvious local voltage drop in the second displaying region, thereby the problem of darkness in the second displaying region is improved, while increasing the transmittance of the second displaying region, the effect of displaying of the display panel is ensured.

### BRIEF DESCRIPTION OF THE DRAWINGS

In order to more clearly illustrate the technical solutions of the embodiments of the present disclosure or the prior art, the figures that are required to describe the embodiments or the prior art will be briefly described below. Apparently, the figures that are described below are embodiments of the present disclosure, and a person skilled in the art can obtain other figures according to these figures without paying creative work.

FIG. 1 illustrates a schematic structural diagram of a display panel according to an embodiment of the present disclosure;

FIG. 2 illustrates a first schematic diagram of the layout of the pixel units and the cathodes that are included by a display panel according to an embodiment of the present disclosure;

FIG. 3 illustrates a second schematic diagram of the layout of the pixel units and the cathodes that are included by a display panel according to an embodiment of the present disclosure;

FIG. 4 illustrates a third schematic diagram of the layout of the pixel units and the cathodes that are included by a display panel according to an embodiment of the present disclosure;

FIG. 5 illustrates a first schematic diagram of the distribution of the cathodes that are included by a display panel according to an embodiment of the present disclosure;

FIG. 6 illustrates a second schematic diagram of the distribution of the cathodes that are included by a display panel according to an embodiment of the present disclosure;

FIG. 7 illustrates a schematic diagram of the distribution of the cathode-removal regions in the first displaying region of a display panel according to an embodiment of the present disclosure;

FIG. 8 illustrates a schematic diagram of the arrangement of the cathodes in the first displaying region of a display panel according to an embodiment of the present disclosure;

FIG. 9 illustrates a schematic diagram of the arrangement of the cathodes in the first displaying region of another display panel according to an embodiment of the present disclosure; and

FIG. 10 illustrates a schematic diagram of the distribution of the regions of a display panel according to an embodiment of the present disclosure.

### REFERENCE NUMBERS

1: first displaying region; 2: second displaying region; 3: third displaying region; 4: cathodes; 5: cathode-removal regions; 6: pixel units; 61: sub-pixel units; 41: first cathodes; and 42: second cathodes.

### DETAILED DESCRIPTION

The technical solutions according to the embodiments of the present disclosure will be clearly and completely described below with reference to the drawings according to the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

It should be understood that the “one embodiment” or “an embodiment” as used throughout the description means that particular features, structures or characteristics with respect to the embodiments are included in at least one embodiment of the present disclosure. Therefore, the “in one embodiment” or “in an embodiment” as used throughout the description does not necessarily refer to the same embodiment. Furthermore, those particular features, structures or characteristics may be combined in one or more embodiments in any suitable form.

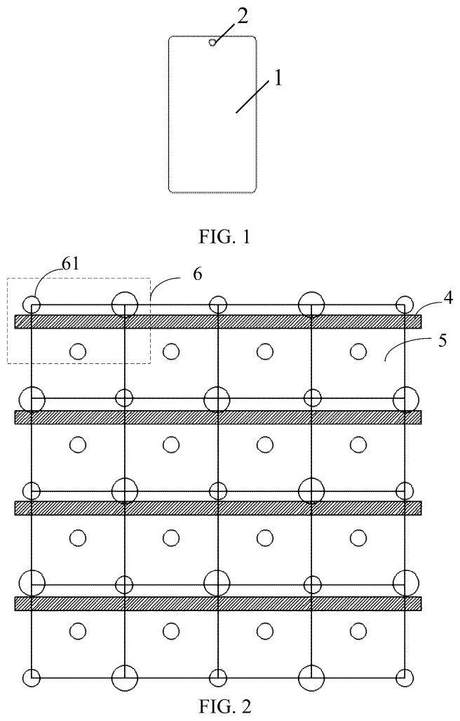

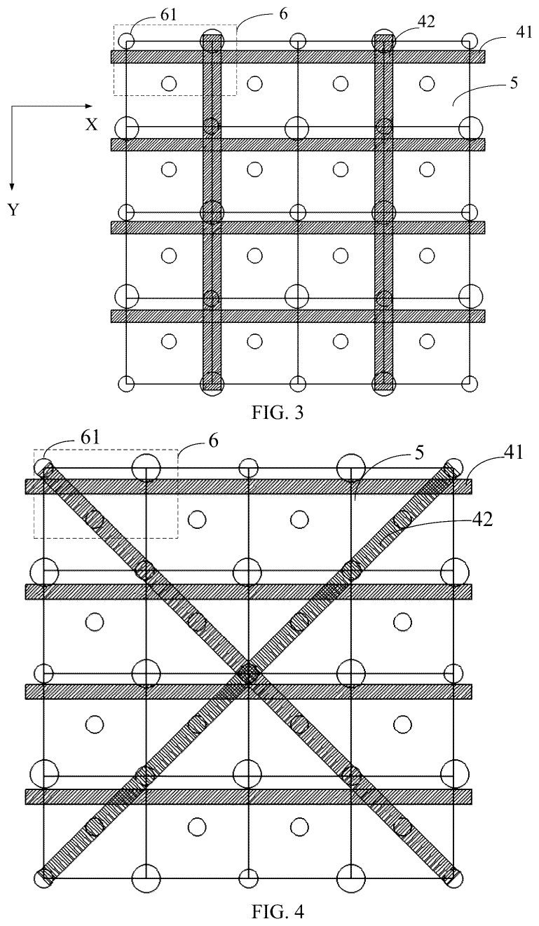

In a first aspect, a display panel is provided by an embodiment of the present disclosure. FIG. 1 illustrates a schematic structural diagram of a display panel according to an embodiment of the present disclosure. FIG. 2 illustrates a first schematic diagram of the layout of the pixel units and the cathodes that are included by a display panel according to an embodiment of the present disclosure. FIG. 3 illustrates a second schematic diagram of the layout of the pixel units and the cathodes that are included by a display panel according to an embodiment of the present disclosure. FIG. 4 illustrates a third schematic diagram of the layout of the pixel units and the cathodes that are included by a display panel according to an embodiment of the present disclosure. As shown in FIGS. 1, 2, 3 and 4, a display panel is provided by an embodiment of the present disclosure, wherein the display panel includes a first displaying region 1 and a second displaying region 2. The second displaying region 2 is located within the first region of the displaying surface of the display panel. There are a plurality of cathodes 4 that are arranged in a predetermined pattern and a plurality of cathode-removal regions 5 in the second displaying region 2, and at least two cathodes 4 in the plurality of cathodes 4 are connected in parallel. The first region refers to a region that faces a region of a bottom of the displaying surface of the display panel where an optical functional element is disposed.

The first displaying region 1 refers to the primary region that plays a role in displaying in the display panel. The second displaying region 22 refers to a region that faces the region of the bottom of the displaying surface of the display panel where an optical functional element is disposed. The second displaying region 2 may be located at any position of the displaying surface of the display panel, wherein the specific position is determined according to the position in the display panel where the optical functional element is disposed. The optical functional element may be an optical element such as a camera and a photosensor, which is not limited in the embodiments of the present disclosure. In addition, the shape of the second displaying region 2 may be any shape such as a circle, a square, an ellipse, a rhombus, a polygon and an irregular pattern, which is not limited in the embodiments of the present disclosure.

In order to realize the optical effect and the displaying effect of the display panel at the second displaying region 2, in the embodiments of the present disclosure, there are a plurality of cathodes 4 that are arranged in a predetermined pattern, and a plurality of cathode-removal regions 5 in the second displaying region 2. In this way, under the effect of the cathode-removal regions 5, the pixel density of the second displaying region 2 is less than the pixel density of the first displaying region 1. In other words, the area of the gap between two neighboring pixel units 6 within the second displaying region 2 is increased as compared with the area of the gap between two neighboring pixel units 6 within the first displaying region 1, wherein the gap refers to the region of the first displaying region 1 or the second displaying region 2 where no pixel unit 6 is disposed, thus the transmittance of the second displaying region 2 is less than the transmittance of the first displaying region 1. It should be noted that, in the embodiments of the present disclosure, the pixel units 6 refer to the base units that constitute the basic primary color pigments and the grayscales of the display panel, wherein each of the pixel units 6 includes one red sub-pixel, one green sub-pixel and one blue sub-pixel.

In addition, it should be noted that the cathode-removal regions 5 may be formed by using the method that the cathodes 4 are firstly deposited by using the whole-face vapor-deposition, and then patterning removal is performed by using a laser technique. The cathode-removal regions 5 may also be formed by using the method of performing vacuum vapor-deposition by using a vapor-deposition mask, which particularly includes: before the vapor deposition of the cathodes 4, firstly, by using a patterning mask, a layer of a material (which is referred to as an inhibitor) repulsive to the material of the cathodes 4 is vapor-deposited, wherein the pattern of the inhibitor material of the cathodes 4 is the same as the pattern of the removed part of the cathodes 4. After the inhibitor material has been completely deposited, the whole-face cathodes 4 are deposited. Because of the repulsive effect of the material, the cathodes 4 cannot be adhered to the region that has already had the inhibitor pattern, thereby the patterning removal of the cathodes 4 is realized. The plurality of cathodes 4 arranged in the predetermined pattern are formed in the second displaying region 2, and the cathode-removal regions 5 are formed at the cavity parts among the plurality of cathodes 4. In addition, the display panel further includes a substrate base board, and the projections, on the substrate base board, of the cathode-removal regions 5 and the luminescent layers of the pixel units 6 in the second displaying region 2 do not overlap. In this way, it can be ensured that the cathode-removal regions 5 do not affect the normal displaying of the second displaying region 2 to ensure the effect of displaying of the second displaying region 2.

Further, the removal of the cathodes 4 may cause the plurality of cathodes 4 to be connected in series together, so that the resistance of the cathodes 4 is increased, which affects the effect of displaying of the displaying base board. In view of the above, in the embodiments of the present disclosure, at least two cathodes 4 in the plurality of cathodes 4 are connected in parallel, thus the resistance of the cathodes 4 is reduced.

It can be seen from the above embodiments that, in the embodiments of the present disclosure, because the second displaying region 2 is located within the first region of the displaying surface of the display panel, the first region refers to a region that faces the region of the bottom of the displaying surface of the display panel where an optical functional element is disposed, and there are a plurality of cathodes 4 that are arranged in a predetermined pattern and a plurality of cathode-removal regions 5 in the second displaying region 2, under the effect of the cathode-removal regions 5, the pixel density of the second displaying region 2 is less than the pixel density of the first displaying region 1; in other words, the transmittance of the second displaying region 2 is less than the transmittance of the first displaying region 1, to satisfy the demand on light sensation of the functional elements. In addition, because at least two cathodes 4 in the plurality of cathodes 4 are connected in parallel, the resistance of the cathodes 4 can be reduced to prevent obvious local voltage drop in the second displaying region 2, thereby the problem of darkness in the second displaying region 2 is improved, while increasing the transmittance of the second displaying region 2, the effect of displaying of the display panel is ensured.

In addition, regarding the above cathodes 4, the cathodes 4 may be arranged in a predetermined pattern, wherein the predetermined pattern is a pattern that is formed by arranging the plurality of cathodes 4 in a certain sequence, for example, a net-like pattern, a grid pattern and a strip shape, which is not limited in the embodiments of the present disclosure.

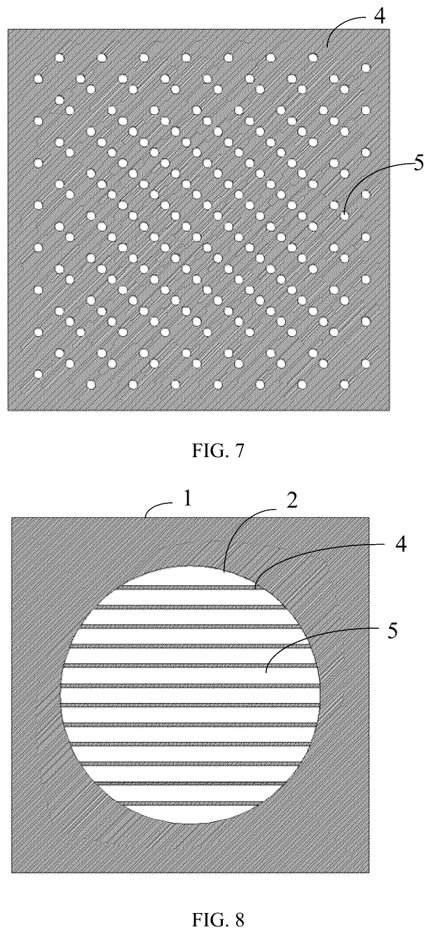

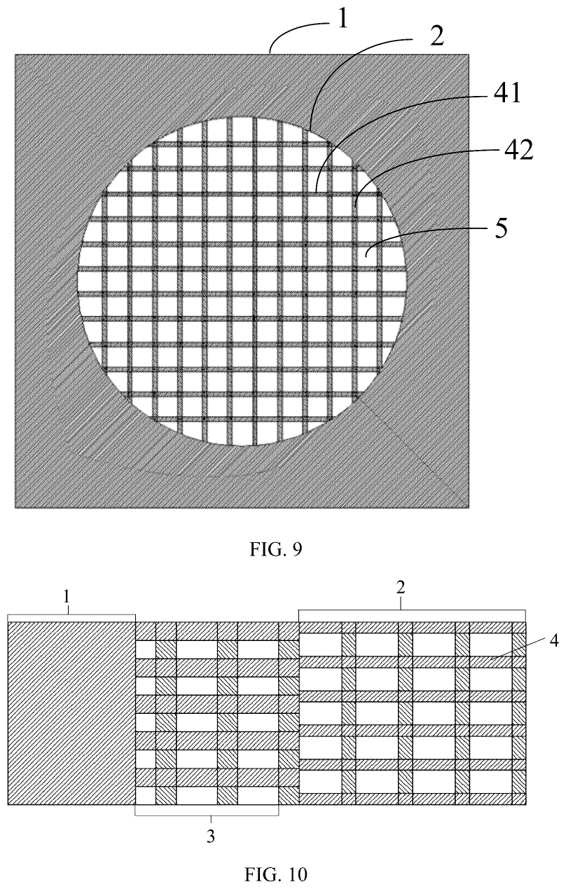

In some embodiments, as shown in FIGS. 8 and 9, the plurality of cathodes 4 contained in the second displaying region 2 are arranged in a net-like pattern. It should be noted that the plurality of cathodes 4 may extend along a pixel row direction, and the plurality of cathodes 4 are arranged equidistantly, to cause the plurality of cathodes 4 to be parallel, so as to cause the plurality of cathodes 4 in the second displaying region 2 to form a transverse grid structure. In the present embodiment, each two neighboring cathodes 4 enclose one cathode-removal region 5, and a shape of the cathode-removal regions 5 are strip-shaped. Alternatively, cathodes 4 extending along the pixel column direction may be further included, so that the cathodes 4 along the pixel row direction and the cathodes 4 along the pixel column direction intersect. In the present embodiment, the four cathodes 4 that are arranged in stagger enclose one cathode-removal region 5, and the shape of the cathode-removal regions 5 is a square or a rhombus. In this way, the plurality of cathodes 4 extending along the pixel row direction can BE facilitated to be connected in parallel to reduce the resistance.

Optionally, as shown in FIGS. 3 and 4, there are first cathodes 41 and second cathodes 42 in the second displaying region 2. The first cathodes 41 extend along the pixel row direction, and multiple first cathodes 41 are arranged equidistantly along a pixel column direction. The second cathodes 42 and the first cathodes 41 intersect, so that a plurality of first cathodes 41 are connected in parallel.

It should be noted that the spacing between each two neighboring cathodes 4 is determined according to the transmittance that is required by the second displaying region 2; in other words, the size along the pixel row direction of the cathode-removal region 5 formed between each two neighboring cathodes 4 is determined according to the transmittance that is required by the second displaying region 2. The quantity of the second cathodes 42 may be equal to the quantity of the first cathodes 41, and may also be less than the quantity of the first cathodes 41, which is not limited in the embodiments of the present disclosure. It should also be noted that each of the second cathodes 42 is required to have connection relations with all of the first cathodes 41; in other words, one second cathode 42 is connected to each of the first cathodes 41. As an example, taking that the quantity of the first cathodes 41 is five and the quantity of the second cathodes 42 is two as an example, the five first cathodes 41 are arranged sequentially along the pixel column direction, one of the second cathodes 42 is connected to a first side of the five first cathodes 41, and the other of the second cathodes 42 is connected to a second side of the five first cathodes 41. In this way, the second cathodes 42 and the first cathodes 41 are equivalent to be a parallel circuit, so that the resistance within the second displaying region 2 is reduced. In the embodiments of the present disclosure, the pixel row direction and the pixel column direction are two directions that are perpendicular to each other in the plane where the display panel is located. In the pixel matrix, the pixel row direction may be understood as the extending direction of each of the rows of the pixels in the pixel matrix, and the pixel column direction may be understood as the extending direction of each of the columns of the pixels in the pixel matrix. The pixel row direction is, for example, the direction shown by the X in FIG. 3, and the pixel column direction is, for example, the direction shown by the Y in FIG. 3.

In some alternative implementations, as shown in FIG. 4, the included angle between each of the first cathodes 41 and each of the second cathodes 42 is an acute angle. In the present embodiment, the plurality of first cathodes 41 may be equivalent to a rectangular region, and the second cathodes 42 are arranged along the diagonal lines of the matrix region, so that the plurality of first cathodes 41 are connected in parallel via the second cathodes 42. It should be noted that the shapes of the cathode-removal regions 5 enclosed by the first cathodes 41 and the second cathodes 42 are triangles and trapezoids, and the areas of the plurality of cathode-removal regions 5 are unequal.

In some other alternative implementations, as shown in FIG. 3, the included angle between each of the first cathodes 41 and each of the second cathodes 42 is a right angle. In the present embodiment, the plurality of first cathodes 41 may be equivalent to a rectangular region, and the second cathodes 42 are arranged equidistantly alone the direction perpendicular to the two parallel edges of the rectangular region, so that the plurality of first cathodes 41 are connected in parallel via the second cathodes 42. It should be noted that, in the present embodiment, the shapes of the cathode-removal regions 5 formed by the first cathodes 41 and the second cathodes 42 are rectangles. Particularly, in order to make the areas of the cathode-removal regions 5 formed between the first cathodes 41 and the second cathodes 42 to be equal, the plurality of first cathodes 41 are arranged equidistantly, the plurality of second cathodes 42 are arranged equidistantly, the quantity of the first cathodes 41 and the quantity of the second cathodes 42 are equal, and the spacing between each two neighboring first cathodes 41 is equal to the spacing between each two neighboring second cathodes 42.

In addition, in order to further reduce the resistance within the second displaying region 2, in some embodiments, the display panel further includes a substrate, the cathodes are disposed on the substrate, and a light-exiting adjusting component is disposed at the side of the cathodes away from the substrate. It should be noted that, from the resistance formula R=ρL/S (wherein ρ represents the electrical resistivity of the resistor, and is decided by the property of itself, L represents the length of the resistor, and S represents the cross-sectional area of the resistor), it can be obtained that, by disposing the light-exiting adjusting component at the side of the cathodes 4 away from the substrate, the cross-sectional areas of the cathodes 4 can be increased, thereby the resistance is further reduced.

Optionally, the material of the cathodes 4 is a metal or an alloy, and the material of the light-exiting adjusting component is a metal oxide. It should be noted that the cathodes 4 may be of a metal material such as silver, aluminum, lithium, magnesium and indium, and may also be an alloy material such as a magnesium-silver alloy or an aluminum-lithium alloy, and the material of the light-exiting adjusting component may be indium tin oxide, aluminium oxide or magnesium oxide, which are not limited in the embodiments of the present application.

As an example, taking that the cathodes 4 are of a magnesium-silver alloy as an example, in some embodiments, the resistance of the cathodes may also be reduced by regulating the ratio of the magnesium-silver alloy. Generally, the magnesium-silver ratio of the magnesium-silver alloy is 10:1.

If the magnesium-silver ratio of the magnesium-silver alloy is reduced to 9:1 or 8:1 or lower, because the electrical resistivity of magnesium is greater than the electrical resistivity of silver, under the condition that the relative proportion of silver is increased, the resistance of the cathodes 4 can be reduced.

In addition, it should also be noted that the transmittance of the light-exiting adjusting component is greater than the transmittance of the cathodes 4, so as to ensure that the light-exiting adjusting component does not affect the overall light-transmitting performance of the first displaying region 1 and the second displaying region 2.

An indium-tin-oxide layer is vapor-deposited on the surface of the cathodes 4. It should be noted that, from the resistance formula R=ρL/S (wherein ρ represents the electrical resistivity of the resistor, and is decided by the property of itself, L represents the length of the resistor, and S represents the cross-sectional area of the resistor), it can be obtained that, by vapor-depositing the indium-tin-oxide layer on the surface of the cathodes 4, the cross-sectional areas of the cathodes 4 can be increased, thereby the resistance is further reduced.

It should also be noted that, if the plurality of cathodes 4 surround a certain sub-pixel unit 61, the resistance of this sub-pixel unit 61 may be increased, resulting in local darkness at the position of that sub-pixel unit 61, the effect of displaying of the display panel is affected. Therefore, in the embodiments of the present disclosure, the cathodes 4 are required to be distributed evenly, to prevent local darkness and color cast.

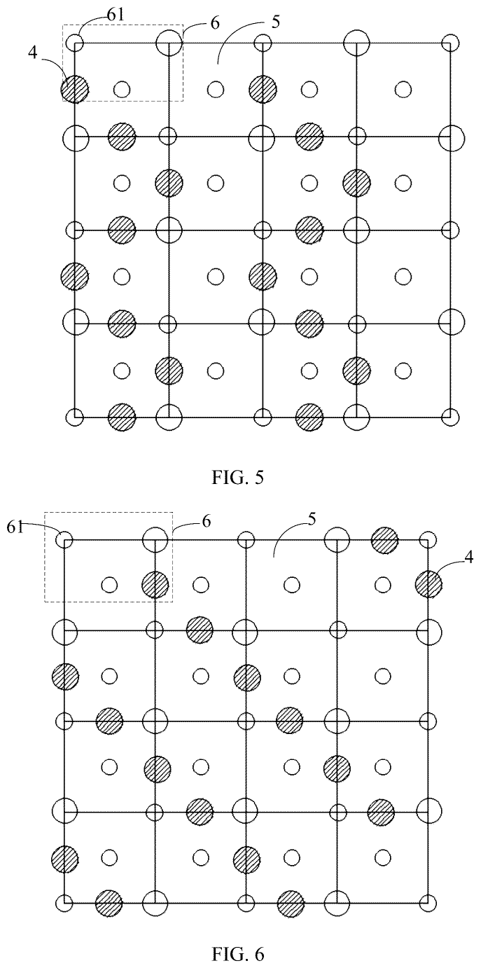

Based on this, in an embodiment of the present disclosure, as shown in FIGS. 5 and 6, the display panel includes a plurality of pixel units 6, each of the pixel units 6 includes a plurality of sub-pixel units 61 of different colors, and distances between each of the cathodes 4 and each of the sub-pixel units 61 of neighboring pixel units 6 are equal.

It should be noted that the plurality of pixel units 6 are arranged in a predetermined matrix, for example, a matrix of 8 rows and 8 columns, so that the sub-pixel units 61 of the same color in each of the pixel units 6 are also arranged in a matrix, and there is a gap between two neighboring pixel units 6. The cathodes 4 are disposed in the gaps between two neighboring pixel units 6, and the cathodes 4 are evenly distributed among the plurality of pixel units 6, so that finally distances between each of the cathodes 4 and each of the sub-pixel units 61 of neighboring pixel units 6 are equal. In this way, local darkness at the positions of the pixel units 6 can be prevented, color cast is prevented and the effect of displaying of the display panel is improved. It should also be noted that the cathodes 4 may be arranged evenly in the arrangement modes shown in FIGS. 5 and 6. In FIG. 5, the cathodes 4 are arranged along the pixel row direction in even zigzag lines, so that distances between two neighboring cathodes 4 are equal, so as to ensure that the distances between each of the cathodes 4 and each of the sub-pixel units 61 of neighboring pixel units 6 are equal. In FIG. 6, the cathodes 4 are arranged in the oblique direction evenly according to the quantity of the pixel units 6, which can also ensure that the distances between each of the cathodes 4 and each of the sub-pixel units 61 of neighboring pixel units 6 are equal. The particular arrangement mode of the cathodes 4 is determined according to the distribution of the pixel units 6 and the vapor-deposition process of the cathodes 4, and is not limited in the embodiments of the present disclosure. In addition, it should also be noted that the display panel further includes auxiliary leads, and the plurality of pixel units 6 are electrically connected via the auxiliary leads. In order to further increase the transmittance of the first displaying region 1, the spacing between each two neighboring auxiliary leads may be increased. It should also be noted that the distances between each of the cathodes 4 and each of the sub-pixel units 61 of neighboring pixel units 6 may be understood as the distances between the orthographic projection on the substrate of each of the cathodes 4 and the orthographic projections on the substrate of each of the sub-pixel units 61 of the neighboring pixel units 6.

Optionally, in some embodiments, each of the pixel units 6 includes a red sub-pixel unit, a green sub-pixel unit and a blue sub-pixel unit. The red sub-pixel units and the green sub-pixel units are arranged alternately and separately along the pixel row direction, and the red sub-pixel units and the green sub-pixel units are arranged alternately and separately along the pixel column direction. The blue sub-pixel units are located between two rows of the green sub-pixel units and the red sub-pixel units that are arranged alternately and separately.

It should be noted that the pixel row direction and the pixel column direction are two directions that are perpendicular to each other in the plane where the display panel is located. In the pixel matrix, the pixel row direction may be understood as the extending direction of each of the rows of the pixels in the pixel matrix, and the pixel column direction may be understood as the extending direction of each of the columns of the pixels in the pixel matrix. The pixel row direction is, for example, the direction shown by the X in FIG. 3, and the pixel column direction is, for example, the direction shown by the Y in FIG. 3. In an embodiment of the present application, the red sub-pixel unit, the green sub-pixel unit and the blue sub-pixel unit that are included by each of the pixel units 6 may be distributed in a triangle, the red sub-pixel and the green sub-pixel are located in the same straight line along the pixel row direction, and the blue sub-pixel units are located between two rows of the green sub-pixel units and the red sub-pixel units that are arranged alternately. In other words, if the red sub-pixel unit, the green sub-pixel unit and the blue sub-pixel unit that are included by each of the pixel units 6 are distributed in an isosceles triangle, then the connecting line between the red sub-pixel and the green sub-pixel forms the bottom edge of the isosceles triangle, and the blue sub-pixel is located at a vertex of the isosceles triangle. In this way, the above-described distribution mode of the red sub-pixel unit, the green sub-pixel unit and the blue sub-pixel unit that are included by each of the pixel units 6 facilitates to reasonably configure the cathodes 4, so that the distances between each of the cathodes 4 and each of the sub-pixel units 61 of neighboring pixel units 6 are equal to prevent local darkness at the positions of the pixel units 6, to prevent color cast, and to improve the effect of displaying of the display panel.

In some embodiments, the cathodes 4 are located between neighboring red sub-pixel units and green sub-pixel units in the pixel column direction, or located between neighboring red sub-pixel units and green sub-pixel units in the pixel row direction.

It should be noted that, by using the above-described distribution mode of the red sub-pixel unit, the green sub-pixel unit and the blue sub-pixel unit that are included by each of the pixel units 6, the cathodes 4 can be located between neighboring red sub-pixel units and green sub-pixel units in the pixel column direction, or located between neighboring red sub-pixel units and green sub-pixel units in the pixel row direction, so that the distances between each of the cathodes 4 and each of the sub-pixel units 61 of neighboring pixel units 6 are equal.

Further, the blue sub-pixel units are located in the gaps between two neighboring rows of the green sub-pixel units and the red sub-pixel units that are arranged alternately and separately.

It should be noted that one row of each two neighboring rows of the sub-pixel units may be distributed in stagger and separately in the manner of a red sub-pixel unit, a blue sub-pixel unit, a red sub-pixel unit and a blue sub-pixel unit, and the other row may be distributed separately in the manner of a blue sub-pixel unit, a red sub-pixel unit, a blue sub-pixel unit and a the red sub-pixel, so that in the pixel column direction, the sub-pixel units are distributed in stagger and separately in the manner of a red sub-pixel unit, a blue sub-pixel unit, a red sub-pixel unit and a blue sub-pixel unit. In this way, a red sub-pixel unit, a green sub-pixel unit, a green sub-pixel unit and a red sub-pixel unit form a square sub-pixel-unit arrangement grid, so that the blue sub-pixel unit is located at the center position of the square sub-pixel-unit arrangement grid. In this way, each of the cathodes 4 can be located at the center positions of the two sides of any neighboring square sub-pixel-unit arrangement grids; in other words, it can be ensured that the distances between each of the cathodes 4 and each of the sub-pixel units 61 of neighboring pixel units 6 are equal.

In some embodiments, each of the pixel units includes a red sub-pixel unit, a green sub-pixel unit and a blue sub-pixel unit. The red sub-pixel unit, the green sub-pixel unit and the blue sub-pixel unit that are included by each of the pixel units surround one cathode, and the cathode 4 deviates from the blue sub-pixel unit.

It should be noted that, in the present embodiment, the distance between each of the cathodes 4 and the red sub-pixel unit included by each of the pixel units may be equal to the distance between each of the cathodes 4 and the green sub-pixel unit included by each of the pixel units, wherein that distance may be expressed as a first distance, and the distance between each of the cathodes 4 and the blue sub-pixel unit included by each of the pixel units is a second distance. The second distance is caused to be greater than the first distance, so that the cathode 4 deviates from the blue sub-pixel unit, so as to prevent the cathodes 4 from being arranged around the blue sub-pixel unit, to prevent increasing the resistance of the blue sub-pixel unit, to prevent excessive darkness of the blue sub-pixel unit. It should also be noted that the above-described case where the cathode 4 deviates from the blue sub-pixel unit is merely an exemplary embodiment, if the case of excessive darkness of the red sub-pixel unit or excessive darkness of the green sub-pixel unit happens, i.e., the case where all of the cathodes 4 are arranged around the red sub-pixel unit or all of the cathodes 4 are arranged around the green sub-pixel unit, the cathode 4 may deviate from the red sub-pixel unit or the cathode 4 may deviate from the green sub-pixel unit.

Further, in some embodiments, the cathodes 4 are arranged in an array. It should be noted that the cathodes 4 may form a square array that the row quantity and the column quantity are equal, may also form a rectangular array that the row quantity and the column quantity are unequal, and may also form a rhombic array in the oblique directions. In this way, when the cathodes 4 are arranged in an array, because the spacings between each two neighboring cathodes 4 are equal, it can be ensured that the distances between each of the cathodes 4 and each of the sub-pixel units 61 of neighboring pixel units 6 are equal.

In some other embodiments, as shown in FIG. 7, the second displaying region 2 includes a middle region and a peripheral region surrounding the middle region, and the quantity of the cathode-removal regions 5 disposed in the middle region is greater than the quantity of the cathode-removal regions 5 disposed in the peripheral region.

It should be noted that, because the middle region of the second displaying region 2 is required to have a higher transmittance than the transmittance of the peripheral region of the second displaying region 2, it is required to dispose the cathode-removal regions 5 of a higher quantity within the middle region, so as to satisfy the demand of the middle region on a higher transmittance. In an embodiment of the present disclosure, the quantity of the cathode-removal regions 5 disposed in the middle region is greater than the quantity of the cathode-removal regions 5 disposed in the peripheral region. Therefore, not only can the demand of the middle region on a higher transmittance be satisfied, but the higher resistance of the middle region can also be neutralized by using the lower resistance of the peripheral region, to prevent a large pixel resistance of the middle region. It should also be noted that, taking that the second displaying region 2 is square as an example, in the directions of the diagonal lines of the second displaying region 2, the quantity of the cathode-removal regions 5 located adjacent to the intersection point of the two diagonal lines is greater than the quantity of the cathode-removal regions 5 located at the four corners, and, in the directions of the diagonal lines, in the directions from the center to the periphery, the spacings between each two neighboring cathode-removal regions sequentially increase.

Further, in some embodiments, the quantity of the cathode-removal regions 5 progressively increases from the peripheral region to the middle region.

It should be noted that the cathode-removal regions 5 may sequentially progressively increase in the directions from the peripheral region to the middle region in an arithmetic progression, and may also sequentially progressively increase in the directions from the peripheral region to the middle region in a geometric progression, and is not limited in the embodiments of the present disclosure. As an example, it is also taken as an example that the second displaying region 2 is a square region, the plurality of cathode-removal regions 5 may be arranged obliquely in the directions of the diagonal lines, the quantities of one row of the cathode-removal regions 5 formed at the two sides of the diagonal lines sequentially progressively decrease in the directions from the center to the corners, and, in each of the rows of the cathode-removal regions 5, in the directions from the center to the corners, the spacings between each two neighboring cathode-removal regions sequentially increase.

In addition, in an embodiment of the present disclosure, in the second displaying region 2, the ratio of the area occupied by the cathode-removal regions 5 to the area occupied by the cathodes 4 is between 0.1 and 1.

It should be noted that the ratio of the area occupied by the cathode-removal regions 5 to the area occupied by the cathodes 4 decides the transmittance of the second displaying region 2. When the ratio of the area occupied by the cathode-removal regions 5 to the area occupied by the cathodes 4 increases, the transmittance of the second displaying region 2 increases. When the ratio of the area occupied by the cathode-removal regions 5 to the area occupied by the cathodes 4 decreases, the transmittance of the second displaying region 2 decreases. In this way, when the ratio of the area occupied by the cathode-removal regions 5 to the area occupied by the cathodes 4 is between 0.1 and 1, the cathode-removal regions 5 and cathodes 4 are not limited to a certain ratio, so that, in the second displaying region 2, the ratio can be selected flexibly according to the demand of transmission of the internally disposed optical devices.

In addition, in some embodiments, the pixel density of the second displaying region 2 is a preset multiple of the pixel density of the first displaying region 1, so that the transmittance of the second displaying region 2 is greater than the transmittance of the first displaying region 1.

It should be noted that, in order to improve the optical effect and the displaying effect of the display panel at the second displaying region 2, the pixel density of the second displaying region 2 is a preset multiple of the pixel density of the first displaying region 1, the preset multiple is a multiple value less than 1 and greater than 0; for example, the pixel density of the second displaying region 2 is any multiple of the pixel density of the first displaying region such as ⅔, ½, ⅓ and ¼. In this way, the area of the gap between two neighboring pixel units 6 in the second displaying region 2 is increased as compared with the area of the gap between two neighboring pixel units 6 in the first displaying region 1, wherein the gap refers to the region of the first displaying region 1 or the second displaying region 2 where no pixel unit 6 is disposed, so that the transmittance of the second displaying region 2 is less than the transmittance of the first displaying region 1.

Optionally, as shown in FIG. 10, the display panel further includes a third displaying region 3.

The third displaying region 3 is located between the first displaying region 1 and the second displaying region 2, and the pixel density of the third displaying region 3 is greater than the pixel density of the second displaying region 2, and less than the pixel density of the first displaying region.

It should be noted that, because the third displaying region 3 is located between the first displaying region 1 and the second displaying region 2, and the pixel density of the third displaying region 3 is greater than the pixel density of the second displaying region 2, and less than the pixel density of the first displaying region, the pixel density of the third displaying region 3 is between the pixel density of the first displaying region and the pixel density of the second displaying region 2, so that the transmittance of the third displaying region 3 is between the transmittance of the first displaying region and the transmittance of the second displaying region 2. In this way, the transmittance of the display panel sequentially progressively decreases along the first displaying region 1, the third displaying region 3 and the second displaying region 2, so that the increasing of the transmittance of the display panel has a transition region, wherein the displaying of the third displaying region 3 plays a role in transition and buffering, thus obvious boundary difference caused by the pixel unbalance between the first displaying region 1 and the second displaying region 2 is prevented, so as to improve the uniformity of the brightnesses and the displaying of the display panel.

It should also be noted that, in an alternative implementation, the pixel-density value of the first displaying region 1, the pixel-density value of the third displaying region 3 and the pixel-density value of the second displaying region 2 are in an arithmetic progression; in other words, the difference between the pixel-density value of the third displaying region 3 and the pixel-density value of the first displaying region 1 is equal to the difference between the pixel-density value of the second displaying region 2 and the pixel-density value of the third displaying region 3, so that the transmittances of the display panel is caused to be evenly distributed and progressively decrease along the first displaying region 1, the third displaying region 3 and the second displaying region 2, which facilitates to further prevent obvious boundary difference caused by the pixel unbalance between the first displaying region 1 and the second displaying region 2.

In another alternative implementation, the pixel-density value of the first displaying region 1, the pixel-density value of the third displaying region 3 and the pixel-density value of the second displaying region 2 are in a geometric progression. Because the pixel-density value of the first displaying region 1, the pixel-density value of the third displaying region 3 and the pixel-density value of the second displaying region 2 are in an arithmetic progression or a geometric progression, the transmittances of the display panel progressively decrease in steps along the first displaying region 1, the third displaying region 3 and the second displaying region 2, which facilitates to further prevent obvious boundary difference caused by the pixel unbalance between the first displaying region 1 and the second displaying region 2.

In some embodiments, the resistance of the cathodes 4 in the third displaying region 3 is greater than the resistance of the cathodes 4 in the second displaying region 2, and less than the resistance of the cathodes 4 in the first displaying region 1. In this way, because the resistance of the cathodes 4 in the third displaying region 3 is greater than the resistance of the cathodes 4 in the second displaying region 2, and less than the resistance of the cathodes 4 in the first displaying region 1, the resistance of the second displaying region 2 can be compensated by using the resistance of the third displaying region 3, so that the resistance is overall in a balanced state, so as to prevent consumption caused by increasing or decreasing of the resistance, so that the effect of displaying of the display panel is maintained at the balanced state.

It can be seen from the above embodiments that, in the embodiments of the present disclosure, because the second displaying region 2 is located within the first region of the displaying surface of the display panel, the first region refers to a region that faces the region of the bottom of the displaying surface of the display panel where an optical functional element is disposed, and there are a plurality of cathodes 4 that are arranged in a predetermined pattern and a plurality of cathode-removal regions 5 in the second displaying region 2, under the effect of the cathode-removal regions 5, the pixel density of the second displaying region 2 is less than the pixel density of the first displaying region 1; in other words, the transmittance of the second displaying region 2 is less than the transmittance of the first displaying region 1, to satisfy the demand on light sensation of the functional elements. In addition, because at least two cathodes 4 in the plurality of cathodes 4 are connected in parallel, the resistance of the cathodes 4 can be reduced, to prevent obvious local voltage drop within the second displaying region 2, thereby the problem of darkness within the second displaying region 2 is improved, while increasing the transmittance of the second displaying region 2, the effect of displaying of the display panel is ensured.

In the second aspect, a display device is further provided by an embodiment of the present disclosure, wherein the display device includes functional devices and the display panel according to any one of the embodiments in the first aspect.

It should be noted that the display device may be a mobile display device such as a mobile phone, a tablet personal computer, a notebook computer, a palmtop, an onboard display device, a wearable device, an ultra-mobile personal computer (UMPC), a netbook and a personal digital assistant (PDA), or a non-mobile display device such as a personal computer (PC), a television set (TV), a teller machine and a self-service machine, which is not specifically limited in the embodiments of the present disclosure. The advantageous effects of the display device are the same as the advantageous effects of the display panel stated above, and are not discussed further in the embodiments of the present disclosure.

The projections, on a substrate base board, of sensing components or function triggering components of the functional elements at least partially overlap with the projections of the cathode-removal regions 5 on the substrate base board. In this way, that the functional elements can sense light normally can be ensured.

Optionally, the functional elements include a camera, an infrared-radiation element, a light-reflection sensing element, an ambient-light sensor, a fingerprint identifying element and a sound emitting element. In this way, when the transmittance of the second displaying region 2 of the display panel is less than the transmittance of the first displaying region 1, because the second displaying region 2 is located within the first region of the displaying surface of the display panel, and the first region refers to a region that faces the region of the bottom of the displaying surface of the display panel where functional elements are disposed, the transmittance of the region that faces the region where the functional elements are disposed within the displaying surface of the display panel is increased as compared with the transmittances of the other regions, so that the functional elements can sense light normally, thereby the optical effect and the displaying effect of the display panel are improved.

It should be noted that the embodiments of the description are described in the mode of progression, each of the embodiments emphatically describes the differences from the other embodiments, and the same or similar parts of the embodiments may refer to each other.

Although alternative embodiments of the embodiments of the present disclosure have been described, once a person skilled in the art has known the essential inventive concept, he may make further variations and modifications on those embodiments. Therefore, the appended claims are intended to be interpreted as including the alternative embodiments and all of the variations and modifications that fall within the scope of the embodiments of the present disclosure.

Finally, it should also be noted that, herein, relation terms such as first and second are merely intended to distinguish one entity from another entity, and that does not necessarily require or imply that those entities have therebetween any such actual relation or order. Furthermore, the terms “include”, or any variants thereof are intended to cover non-exclusive inclusions, so that articles or terminal devices that include a series of elements do not only include those elements, but also include other elements that are not explicitly listed, or include the elements that are inherent to such articles or terminal devices. Unless further limitation is set forth, an element defined by the wording “including a . . . ” does not exclude additional same element in the article or terminal device including the element.

The technical solutions of the present disclosure have been described in detail above. The principle and the embodiments of the present disclosure are described herein with reference to the particular examples. Moreover, for a person skilled in the art, according to the principle and the implementations of the present disclosure, the particular embodiments and the range of application may be varied. In conclusion, the contents of the description should not be understood as limiting the present disclosure.

1. A display panel, wherein the display panel comprises a first displaying region and a second displaying region;
the second displaying region is located within a first region of a displaying surface of the display panel;
there are a plurality of cathodes that are arranged in a predetermined pattern and a plurality of cathode-removal regions in the second displaying region, wherein at least two cathodes in the plurality of cathodes are connected in parallel; and
the first region refers to a region that faces a region of a bottom of the displaying surface of the display panel where an optical functional element is disposed.

2. The display panel according to claim 1, wherein the plurality of cathodes contained in the second displaying region are arranged in a net-like pattern.

3. The display panel according to claim 2, wherein there are first cathodes and second cathodes in the second displaying region;
the first cathodes extend along a pixel row direction, and multiple first cathodes are arranged equidistantly along a pixel column direction; and
the second cathodes and the first cathodes intersect, so that the multiple first cathodes are connected in parallel.

4. The display panel according to claim 3, wherein an included angle between each of the first cathodes and each of the second cathodes is an acute angle.

5. The display panel according to claim 3, wherein an included angle between each of the first cathodes and each of the second cathodes is a right angle.

6. The display panel according to claim 1, wherein the display panel further comprises a substrate; and
the cathodes are disposed on the substrate, and a light-exiting adjusting component is disposed at one side of the cathodes away from the substrate.

7. The display panel according to claim 6, wherein a material of the cathodes comprises a metal or an alloy, and a material of the light-exiting adjusting component is a metal oxide; and
a transmittance of the light-exiting adjusting component is greater than a transmittance of the cathodes.

8. The display panel according to claim 1, wherein the display panel comprises a plurality of pixel units;
each of the pixel units comprises a plurality of sub-pixel units of different colors;
distances between each of the cathodes and each of the sub-pixel units of neighboring pixel units are equal; and
the cathodes are arranged in an array.

9. The display panel according to claim 8, wherein each of the pixel units comprises a red sub-pixel unit, a green sub-pixel unit and a blue sub-pixel unit;
the red sub-pixel units and the green sub-pixel units are arranged alternately and separately along a pixel row direction, and the red sub-pixel units and the green sub-pixel units are arranged alternately and separately along a pixel column direction; and
the blue sub-pixel units are located between two rows of the green sub-pixel units and the red sub-pixel units that are arranged alternately and separately.

10. The display panel according to claim 9, wherein the cathodes are located between neighboring red sub-pixel units and green sub-pixel units in the pixel column direction, or located between neighboring red sub-pixel units and green sub-pixel units in the pixel row direction.

11. The display panel according to claim 9, wherein the blue sub-pixel units are located in gaps between two neighboring rows of the green sub-pixel units and the red sub-pixel units that are arranged alternately and separately.

12. The display panel according to claim 18, wherein each of the pixel units comprises a red sub-pixel unit, a green sub-pixel unit and a blue sub-pixel unit; and
the red sub-pixel unit, the green sub-pixel unit and the blue sub-pixel unit that are comprised by each of the pixel units surround one cathode, and the cathode deviates from the blue sub-pixel unit.

13. The display panel according to claim 1, wherein the second displaying region comprises a middle region and a peripheral region surrounding the middle region; and
a quantity of the cathode-removal regions disposed in the middle region is greater than a quantity of the cathode-removal regions disposed in the peripheral region.

14. The display panel according to claim 13, wherein the quantity of the cathode-removal regions sequentially increases from the peripheral region to the middle region.

15. The display panel according to claim 1, wherein in the second displaying region, a ratio of an area occupied by the cathode-removal regions to an area occupied by the cathodes is between 0.1 and 1.

16. The display panel according to claim 1, wherein a pixel density of the second displaying region is a preset multiple of a pixel density of the first displaying region, so that a transmittance of the second displaying region is greater than a transmittance of the first displaying region.

17. The display panel according to claim 16, wherein the display panel further comprises a third displaying region; and
the third displaying region is located between the first displaying region and the second displaying region, and a pixel density of the third displaying region is greater than the pixel density of the second displaying region, and less than the pixel density of the first displaying region.

18. The display panel according to claim 17, wherein a resistance of the cathodes within the third displaying region is greater than a resistance of the cathodes within the second displaying region, and less than a resistance of the cathodes within the first displaying region.

19. The display panel according to claim 1, wherein a shape of the second displaying region is any one of a circle, a square, an ellipse, a rhombus, a polygon and an irregular pattern.

20. A display device, wherein the display device comprises functional elements and the display panel according to claim 1; and
projections, on a substrate base board, of sensing components or function triggering components of the functional elements at least partially overlap with projections of the cathode-removal regions on the substrate base board.
